(19) United States
(12) Patent Application Publication
(10) Pub. No.: US 2015/0325715 A1
(43) Pub. Date: Nov. 12, 2015

(54) COMPOSITIONS AND METHODS FOR IMPROVED SOLAR CELLS

(71) Applicant: SUN CHEMICAL CORPORATION, Parsippany, NJ (US)

(72) Inventors: Bo SUN, Bardonia, NY (US); Jin-an HE, Mountain Lakes, NJ (US); Stephen POSTLE, Glen Rock, NJ (US); Joel GARCIA, North Bergen, NJ (US); Ted KREUTZ, Roseland, NJ (US); Robert MATEUSZCZYK, Hopelawn, NJ (US)

(73) Assignee: SUN CHEMICAL CORPORATION, Parsippany, NJ (US)

(21) Appl. No.: 14/648,126

(22) PCT Filed: Dec. 6, 2013
(86) PCT No.: PCT/US13/73589

§ 371 Date: May 28, 2015

Related U.S. Application Data
(60) Provisional application No. 61/737,339, filed on Dec. 14, 2012.
(60) Provisional application No. 61/787,638, filed on Mar. 15, 2013.

(51) Int. Cl. H01L 31/0224; H01L 31/18; H01L 31/068; C09D 5/24; H01L 31/028; H01L 31/0368

(52) U.S. Cl. CPC H01L 31/022425; H01L 31/028; H01L 31/03682; H01L 31/068; C09D 5/24; H01L 31/1804

(57) ABSTRACT

Disclosed are aluminum paste compositions for silicon photovoltaic cells, that display reduced blistering, reduced yellow discoloration, reduced bowing, increased (or maintained) open-circuit voltage (Voc), and possess an increased firing window, through modification of the organic binder and/or addition of pigments. The present invention relates to the improvement of cosmetic and physical properties of silicon photovoltaic cells. The present invention also relates to the use of pigment to reduce the discoloration of fired aluminum pastes on silicon wafers for use as photovoltaic cells.

### CROSS REFERENCE TO RELATED APPLICATIONS

This application claims priority to U.S. Provisional Patent Application Ser. No. 61/737,339, filed Dec. 14, 2012 and U.S. Provisional Patent Application Ser. No. 61/787,638, filed Mar. 15, 2013. All the applications are incorporated herein by reference in the entirety and for all purposes.

### FIELD OF THE INVENTION

The present invention relates to the improvement of cosmetic and physical properties of silicon photovoltaic cells. The present invention also relates to the use of pigment to reduce the discoloration of fired aluminum pastes on silicon wafers for use as photovoltaic cells. The present invention further relates to the use of specific organic media to reduce blistering and yellow discoloration of fired aluminum pastes and bowing of silicon photovoltaic wafers as well as increasing (or maintaining) the open-circuit voltage (Voc) and the firing window of the aluminum pastes on silicon wafers for photovoltaic cells.

### BACKGROUND OF THE INVENTION

The photovoltaic industry is a rapidly growing market, consuming large quantities of backside Aluminum paste (Al paste). There are many Al paste suppliers, and solar cell manufacturers usually select Al paste based on: (1) electrical performance, especially open-circuit voltage (Voc); (2) bowing—during the firing of the wafers, there will be re-solidification and contraction of melted Al, which causes bowing of the entire silicon wafer; (3) firing temperature compatible with front side silver (Ag) paste, which not only can affect electrical performance, but also appearance (bubbling of the backside al layer); and (4) color and appearance of the backside Al layer.

The manufacturing of silicon solar cells in industry includes several steps, for example: 1) Transfer SiO₂ into Si ingot; 2) transfer Si ingot to Si wafer by sawing, etching, doping, and other surface-treatments; 3) screen print and dry aluminum (Al) paste on the backside of the wafer; 4) screen print and dry Ag paste on the backside of the wafer; 5) screen print and dry silver (Ag) paste thin lines on the front side of the wafer; 6) Si wafers with both sides printed are fired in a furnace and the paste on the wafer goes through a temperature curve optimized for front side Ag paste firing. The Al and Ag metals in the two backside Al and Ag pastes form a physical contact with Si through penetrating SiO₂ on the backside, for example. Also, the Al and Ag metals form a contact with each other through the overlapping area. The frontside Ag paste penetrates SiNx anti-reflection layer and reaches n-type Si beneath it. A good contact is formed between Ag and n-Si during the firing. For example, the durations of temperature above 500, 600, 700, 750, and 800° C. during firing usually are about 7.06, 3.90, 2.23, 1.56, and 0.73 seconds, and the peak temperature could reach 815° C. Ag paste could give a 40° C. firing window for the peak temperature. Customers tend to over fire Al paste at a higher co-firing temperature (for example, peak temp. ˜840° C.) when a new front side Ag paste is tested, which tends to cause discoloration of the backside Al layer (a color yellower than the uniform neutral gray appearance following being fired at a standard firing profile). The proposed inventive method of adding color pigments into Al paste can be applied in both the standard firing condition and 20° C. overheating condition for color adjustment, as well as at other temperatures.

Al paste is typically composed of polymer(s), solvent(s), Al powder(s), glass frit(s), and functional additive(s). Examples of polymers include those composed primarily of acrylic resin, epoxy resin, phenol resin, alkyd resin, cellulose polymers, polyvinyl alcohol, rosin and the like. Of these, a cellulose polymer such as ethyl cellulose is especially preferred. The polymers should preferably be able to burn off during firing, no residue after burning is preferred.

Examples of solvents include ethanol, propanol, isopropyl alcohol, ethylene glycol and diethylene glycol derivatives (glycol ether solvents), toluene, xylene, butyl carbitol, terpineol and the like. A proper solvent should be able to sustain paste printing and evaporate thoroughly during drying step.

Non-alloyed, non-coated nodular aluminum powder(s) containing <1% trace elements are preferred in making Al paste. D50 size of Al powder(s) usually is 3˜7 μm, 4˜6 μm is more preferred. D10 is preferred to be >1 μm to minimize the air bubbles shown on Al paste printed on Si wafers during firing. D90 is preferred to be <16 μm to avoid screen-mesh-clogging during printing.

Glass frit(s) are those typically used in the art, comprising for example zinc oxide, borosilicate, alkali metal oxide, barium oxide, bismuth oxide and the like, and mixtures of two or more of these.

Al paste for c-Si solar cells can also include Boron/Bismuth/Zinc-containing glass frits(s), metal organics, rheology-modifying agents, cosmetic-improving additives, adhesive and adhesion-promoting agents, and Al powders. Different metal oxide ingredients and metal organics such as Tri-methyl Borate, Bi₂O₃, V2O5, In₂O₃, and Sb₂O₃ have been claimed by Ferro [US2006/0289055, US2009/0101190] and DuPont [U.S. Pat. No. 7,780,878, US2009/0101199] to improve electronic performance (mainly Voc), bowing, color and appearance (for example, smoothness, bubbling and marbling), and stability of the fired paste in water.

A gray, metallic color is preferred for the Al paste printed on the backside of the wafer and co-fired with the front Ag paste. But sometimes due to the additives for the pastes or certain ingredients (e.g. B, Bi, etc.) in the glass frit or additives, the fired Al paste layer can appear discolored (e.g. brownish or yellowish), which is undesirable as the silicon wafer marketplace equates uniformity of shade on the back surface of cells as an indicator of consistency and quality of manufacturing. Ingredients that may cause the browning or yellowing, are often essential for the paste's Voc, bowing, color and appearance performances, and thus cannot be readily eliminated.

Color, appearance and performance of silicon (Si) wafers' backside aluminum (Al) paste are important properties for Si solar cell manufacturers. The present application provides an easy solution for decreasing discoloration and improving other properties of the Al paste by incorporating pigments into the Al paste. Furthermore, the present application provides for the aluminum paste to be fired at higher temperatures without blistering or other cosmetic defects.

### SUMMARY OF THE INVENTION

The present invention provides an aluminum paste for silicon solar cells comprising: an aluminum powder; a glass frit; an organic resin; a solvent; and an organic or inorganic pigment, wherein said aluminum paste is suited for use in the manufacture of silicon solar cells.

The present invention also provides an aluminum paste for the manufacture of solar cells comprising: (a) an aluminum powders; (b) a glass frit; and (c) an organic medium comprising one or more compounds selected from the group consisting of: a straight or branched chain fatty alcohol, straight or branched chain branched fatty acid, and an acrylic resin.

The present invention further provides processes for making a crystalline silicon solar cell, comprising mixing the aluminum paste compositions of the present invention.

The present invention also provides c-Si solar cells comprising the aluminum paste compositions of the present invention.

These and other objects, advantages, and features of the invention will become apparent to those persons skilled in the art upon reading the details of the methods and formulations as more fully described below.

### DETAILED DESCRIPTION OF THE INVENTION

This present application describes how to reduce the discoloration (yellowing or brownish) color of fired Al paste on Si wafer after firing, and also provides a general method of color tuning by using pigment, preferably inorganic pigment, since many elements with various colors are brought in through the essential ingredients in the paste (e.g. glass frits and additives). Preferably, the inorganic pigment content is about 0.3-2.0% by weight of the total weight of the Al paste of the present invention. Preferably, the pigment comprises cobalt aluminate CoO.Al₂O₃. Also preferably, the pigment is selected from the group consisting of Shepherd Blue 214 and 30C591, and combinations thereof.

In one embodiment, the Al paste of the present invention further comprises one or more from the group consisting of: dispersant(s), metal oxide(s), metal organic additive(s), adhesion promoting agent(s) and thixotropic agent(s).

In another embodiment, the Al paste of the present invention comprises: (a) 0.1-5% inorganic pigment(s); (b) 1.5-10% glass frit(s); (c) 0.2-1.0% dispersant(s); (d) 50-85% Al powder(s); (e) 0.1-2.0% metal organics additive(s); (f) 0-5% metal oxide(s); (g) 0.2-10% resin(s); (h) 5-20% solvent(s); (i) 0-2% thixotropic agent(s); and (j) 0-0.7% adhesion-promoting agent(s). Preferably, the metal organics additive(s) is liquid and is selected from the group consisting of organics of Boron, Zinc, Vanadium, Barium, Strontium, and/or Aluminum, and combinations thereof. More preferably, the metal organic additive is a tri-methyl borate. Also preferably, the dispersant is a fatty acid and the glass frit is selected from the group consisting of B₂O₃, Bi₂O₃, ZnO, SiO₂, Al₂O₃, BaO and combinations thereof.

9. The paste of claim 1 with the Al powder(s) having a particle size in the range of about 1-7 um.

Instead of strenuously developing new glass frits, the present method of achieving color tuning, reduces bowing and provides improved appearance.

The present application describes novel methods and compositions for decreasing discoloration of Al paste by using a heat-stable pigment. Preferably, this pigment is inorganic in nature and more preferably it is a blue or violet pigment for balancing yellow/brown color. Other pigments with different colors could be used for balancing to other colors as needed.

The present application describes color adjustment of Al paste screen printed on the backside of the Si wafer and co-fired with front-side Ag paste. The modification method is direct addition of pigment into the Al paste, preferably 0.1-5% pigment. Several different blue pigments were tested: Cobalt blue from Inframat Advanced Materials; Blue 30C591 (cobalt aluminate); Blue 30C527 (cobalt chromite); and Blue 214 from Shepherd Color (aka B214). Other pigments could also be used, such as for example manganese violets (supplier: Holliday Pigments) and cobalt violets, among others.

The color pigment would preferably be able to endure the high temperature in the furnace during co-firing of Ag pastes and Al paste on the Si wafer. A preferred class of pigments are cobalt aluminate CoO.Al₂O₃ types. B214 pigment is chemically and electronically inert even at the high firing temperature and was found to be a particularly preferred material.

The present also invention provides aluminum paste compositions that are able to reduce blistering, yellow coloring and bowing as well as increase (or maintain) open-circuit voltage (Voc) and the firing window of the paste through modification of the organic binder by adding an organic medium containing either a fatty acid, a branched fatty acid, acrylic resin and/or rosin.

In a preferred embodiment, the aluminum paste comprises: an aluminum powder, glass frit, inorganic additives and an organic binder, wherein the organic binder comprises an organic medium containing at least one of the following: a fatty acid, a branched fatty acid, acrylic resin and rosin.

By modifying the organic binder as indicated above, the present invention achieves certain advantages for aluminum pastes.

For instance, by adding a straight or branched fatty alcohol or a straight or branched fatty acid to the organic portion of the Al paste, the paste can be fired at higher temperatures without blistering or other cosmetic defects. Examples of fatty alcohol include but are not limited to Isofol 12, Isofol 16T, Isofol 18T and Isofol 18E (Sasol) or a branched fatty acid. Examples of branched fatty acid include but are not limited to IsoCarb12, IsoCarb 16 and IsoCarb 18 (Sasol). This higher temperature firing allows for possibly higher Voc, compared to lower firing temperatures, as well as compatibility with front side silver pastes that require higher temperatures for good electrical contact. Furthermore, the dry aluminum layer also has a reduced yellow, more neutral gray color after firing of the paste when compared to standard cells, which is preferred by manufacturers. Bubbling and marbling of the Al paste after firing were also reduced. Bubbling is when the firing of the Al paste creates raised dimples on the rear of the surface and marbling is when the firing creates a web of discoloration—similar to a marble stone.

Fatty alcohols (or long-chain alcohols) are defined as aliphatic alcohols usually consisting of a chain of 8 to 22 carbon atoms, but can have 36 or more carbon atoms. Fatty alcohols usually have an even number of carbon atoms and a single alcohol group (—OH) attached to the terminal carbon. Some are unsaturated and some are branched. They are widely used in industrial chemistry and include for example, myristyl alcohol (C14), lauryl alcohol (C12), and Guerbet alcohols etc.

Fatty acids (or long-chain acids) are defined as aliphatic acids usually consisting of a chain of 8 to 22 carbon atoms, but can have 36 or more carbon atoms. Fatty acids usually have an even number of carbon atoms terminating in a carboxylic acid group and include for example myristic acid (C14), lauric acid (C14), etc.

By adding an acrylic resin, (for example including but not limited to Elvacite 2013, Elvacite 2028, Elvacite 4021, or Elvacite 4111 (Lucite International)) to the organic mixture, some cosmetic gains are observed. The acrylic resin increases the peak firing temperature before the onset of blisters, as well as reduces the yellow color of the fired pastes. It also results in reduced bowing of the paste. This phenomenon occurs due to the mismatch of the thermal expansion factors of aluminum and silicon, and creates a bow in the flat silicon wafer after firing. Increased bowing is related to increased breakage of cells during manufacturing and low bowing is a very desirable trait for an aluminum paste. Furthermore, the acrylic resin reduces the sheet resistance (Rsheet) of the fired aluminum paste, resulting in lower series resistance for the cell and higher efficiency when strung in a module. Blisters, marbling, high bowing and yellowing are all cosmetic traits that are undesirable from a manufacturing standpoint. Preferred acrylics will be thermoplasts of low acid value and MW in the range of about 20,000-500,000, more preferably between about 20,000 and 200,000.

The prior art all describe aluminum pastes which attempt to solve problems with blistering, Voc, bowing and color. The prior art aims to solve these problems by incorporating differences into either the glass frit or aluminum, but none of the prior art aims to solve the problem through modification of the organic medium. As indicated below, there are significant advantages to be realized by using the correct organic binder, and the choice of organic formulation can result in advantages that are preferred by manufacturers and have higher efficiency.

The construction of the Al paste samples requires modifying the organic media of the paste by the addition of the specified fatty alcohol, branched fatty acid, or acrylic resin (or combinations thereof) to the organic medium. Organic media may include 1 to 10% organic polymers that are preferably free of halogen and chloride. The polymers may also be selected from those that are faster and cleaner burning, under the conditions found inside a furnace designed for the production of photovoltaic silicon wafers. A preferred polymer is ethyl cellulose (EC). The organic medium may also include organic solvents from 10 to 90% by weight. The organic solvents preferably have the required solvency power for the particular resin. The organic solvent may be one or more ester alcohols. The organic solvent may also include terpene. In a further exemplary embodiment, the organic solvent may include one or more glycol ethers.

The concentration of specified fatty alcohol, branched fatty acid, or acrylic resin are preferably in the range from 0.1 to 20%, more preferably from 1.0 to 8.0% by total weight of the organic medium. The organic medium is then blended with the aluminum, frit and solvent to form the full paste. In addition to the specified fatty alcohol, branched fatty acid, or acrylic resin, the Al paste may also contain pigments, preferably inorganic pigments as indicated above.

### EXAMPLES 1-3

Example 1 (comparative) is commercially available Al paste Suntronic Cellmet LSF437W1 (Sun Chemical). Example 2 (inventive) is LSF437W1 with 1.2% Shepherd Color Blue 214 pigment added. Example 3 is LSF437W1 with 1.2% blue pigment 30C591 added.

In all examples, pigments are stirred into the paste until a grind of <15 microns is achieved. If necessary, a milling step (3-roll mill or other equipment) could be used to obtain a grind of <15 microns

TABLE 1
Example 1 (Comparative) and Examples 2-3 (Inventive):
Yellow index after addition of Blue Pigment 214
& 30C591 to Suntronic Cellmet LSF437W1

| | Yellow Index | Yellow Index |
|---|---|---|
| | (920° C. | (940° C. |
| Example No. | Zone 4 setting) | Zone 4 setting) |
| Ex. 1 (Comparative): LSF437W1 | 12.33 | 13.13 |
| Ex. 2 (Inventive): LSF437W1 + | 7.67 | 8.22 |
| 1.2% B214 pigment | | |
| Ex. 3 (Inventive): LSF437W1 + | 7.10 | 7.58 |
| 1.2% 30C591 pigment | | |

A lower yellow index number indicates lesser yellowing. Table 1 clearly shows that the addition of pigment improves the yellowing resistance.

### Test Method for Assessing Yellow Index of Examples 1-3 Pastes:

Al paste (1.35 g) was screen printed on the backside of 6-inch multi-crystalline Si wafers obtained from Zhejiang Soco Technology Co. Ltd of China. The paste was dried using BTU International PVD-600 drying furnace with the following settings: belt speed=90 ipm; 310° C. (Zone 1); 290° C. (Zone 2); and 285° C. (Zone 3). The screen used for printing was 325 mesh, 23 micron wire diameter, and 10 micron emulsion, 45 degree bias. The Squeegee used was 65-75 shore in hardness. The wafers were fired using BTU International PVD-600 firing furnace with the following settings: belt speed=105 ipm; 700° C. (Zone 1); 640° C. (Zone 2); 720° C. (Zone 3); and 920° C. (Zone 4) for one test; and 940° C. for a second test. The color of the fired backside Al paste was measured using SpectroEye spectrodensitometer giving a reading of Yellowness Index—ASTM E313. The results are shown in Table 1. A higher yellow index number represents a higher degree of yellowing or discoloration, thus a lower yellow index is preferred.

### EXAMPLES 4-9

Examples 4-9 (Inventive) relate to adding different amounts of preferred pigment B214 to the composition of Example 1.

Table 2 shows examples of adding B214 to LSF437W1 pigments at various amounts and the effect each amount has on reducing discoloration. Though other pigments were found to be effective and are within the scope of the present invention, applicants found that cobalt blue from Inframat Advanced materials tended to darken the color and thus is less preferred though is still suitable for use. Blue 30C527 was not as effective as B214 in reducing discoloration though is still suitable for use. B214 was found to be comparable to Blue 30C591 in reducing discoloration, but B214 has the advantage of a smaller particle size (fineness of grind—FOG) which makes for finer and easier dispersing. Thus, B214 is a preferred material. Further, B214 was shown to have a minimal effect on Voc performance (Tables 3, 6); is very effective in reducing the yellowness (Tables 1, 2, 6); exhibits the benefit of lower bowing (Tables 4 and 6); and imparts better cosmetic appearance in the way of reduced bubbling on the fired Al paste surface (Tables 5 and 6).

TABLE 2
Example 1 (Comparative) and Examples 4-9 (Inventive): Improved
discoloration using differing amounts of preferred pigment B214

| Example No. | Yellow Index |
|---|---|
| Ex. 1 (Comparative): LSF437W1 | 15.03 |
| Ex. 4 (Inventive): LSF437W1 + 1.5% B214 | 6.27 |
| Ex. 5 (Inventive): LSF437W1 + 1.1% B214 | 8.52 |
| Ex. 6 (Inventive): LSF437W1 + 1.0% B214 | 8.69 |
| Ex. 7 (Inventive): LSF437W1 + 0.9% B214 | 8.97 |
| Ex. 8 (Inventive): LSF437W1 + 0.8% B214 | 9.22 |
| Ex. 9 (Inventive): LSF437W1 + 1.05% B214 | 8.64 |

Test Method for Assessing Yellow Index of Examples 1 & 4-9 Pastes in Table 2:

Al paste (1.35 g) was screen printed on the backside of 6-inch multi-crystalline Si wafers obtained from Zhejiang Soco Technology Co. Ltd of China. The paste was dried using BTU International PVD-600 drying furnace with the following settings: of belt speed=90 ipm; 310° C. (Zone 1); 290° C. (Zone 2); and 285° C. (Zone 3). The screen used for printing was 325 mesh, 23 micron wire diameter, and 10 micron emulsion, 45 degree bias. The Squeegee used was 65-75 shore in hardness. The wafers were fired using BTU International PVD-600 firing furnace with the following settings: belt speed=85 ipm; 700° C. (Zone 1); 640° C. (Zone 2); 640° C. (Zone 3); and 880° C. (Zone 4). The color of the fired backside Al paste was measured using SpectroEye spectrodensitometer (X-Rite) giving a reading of Yellowness Index—ASTM E313. The results are shown in Table 2. Table 2 shows that the addition of pigment to the Al paste decreases discoloration (yellowing).

### EXAMPLES 10-12

Examples 4-9 (Inventive) relate to adding different amounts of preferred pigment B214 to the composition of Example 1.

TABLE 3
Example 1 (Comparative) and Examples
10-12 (Inventive): Voc performance.

| Example No. | Voc |
|---|---|
| Ex. 1 (Comparative): LSF437W1 | 0.6190 |
| Ex. 10 (Inventive) LSF437W1 + 0.3% B214 | 0.6188 |
| Ex. 11 (Inventive) LSF437W1 + 0.5% B214 | 0.6187 |
| Ex. 12 (Inventive) LSF437W1 + 0.8% B214 | 0.6189 |

Test Method for Assessing Voc Performance of Examples 1 and 10-12 Pastes in Table 3:

Five-inch mono-crystalline Si wafers obtained from Canadian solar Inc. of Canada were used. Al paste (1.0 gram) was screen printed on backside of the Si wafers. The paste was dried using BTU International PVD-600 drying furnace with the following settings: belt speed=90 ipm; 310° C. (Zone 1); 290° C. (Zone 2); and 285° C. (Zone 3). The screen used for printing was 325 mesh, 23 micron wire diameter, and 10 micron emulsion, 45 degree bias. The squeegee used was 65-75 shore in hardness.

Ag paste was screen printed on the front surface of the wafers, and dried in the drying furnace with the following settings: belt speed=165 ipm; 340° C. (Zone 1); 370° C. (Zone 2); and 370° C. (Zone 3). The screen used for printing was 325 mesh, 23 micron wire diameter, and 16 micron emulsion, 22.5 degree bias. The squeegee used was 65-75 shore in hardness. The wafers were fired using BTU International PVD-600 firing furnace with the following setting: belt speed=200 ipm; 850° C. (Zone 1); 790° C. (Zone 2); 790° C. (Zone 3); and 1000° C. (Zone 4). The electrical performance [open-circuit voltage Voc (V), efficiency, fill factor, series resistance and shunt resistance in the dark and under light] is measured on PV Measurements I-V tester. Table 3 shows that pigment addition had little effect on Voc

TABLE 4
Example 1 (Comparative) and Examples
10-12 (Inventive): Wafer bowing.

| Example No. | Bowing (mm) |
|---|---|
| Ex. 1 (Comparative): LSF437W1 | 2.24 |
| Ex. 10 (Inventive) LSF437W1 + 0.3% B214 | 2.08 |
| Ex. 11 (Inventive) LSF437W1 + 0.5% B214 | 1.96 |
| Ex. 12 (Inventive) LSF437W1 + 0.8% B214 | 1.94 |

Test Method for Assessing Bowing Performance of Examples 1 and 10-12 Pastes in Table 4:

Wafers were prepared identically as those in Table 3 above. The laser used was Keyence LK-H052, wavelength 650 nm. With an unprinted blank wafer on a flat surface, the thickness number was zeroed. The unprinted blank wafer was then removed. On a flat surface, place a wafer was placed with pastes printed and fired. The wafer was centered in the middle of the red laser beam. The readout was taken from the thickness display for the laser as the number of bowing (mm). Bowing was characterized by the distance between the top middle-point of the wafer and bottom contact points on a flat surface. The results are shown in Table 4. Table 4 shows that the addition of pigment decreases bowing (i.e. flatter wafer). It is known in the art that a flatter wafer is advantageous for the construction of solar panels as well as other electrical panels.

TABLE 5
Example 1 (Comparative) and Examples 10-12
(Inventive): Appearance (bubbling).

| Example No. | Bubble (%) |
|---|---|
| Ex. 1 (Comparative): LSF437W1 | 68 |
| Ex. 10 (Inventive) LSF437W1 + 0.3% B214 | 46 |
| Ex. 11 (Inventive) LSF437W1 + 0.5% B214 | 31 |
| Ex. 12 (Inventive) LSF437W1 + 0.8% B214 | 30 |

Test Method for Assessing Appearance (Bubbling) of Examples 1 and 10-12 Pastes in Table 5:

Wafers were prepared identically as those in Table 3 above. The percentage of bubble area was assessed visually and expressed as a %. The results in Table 5 are an average of 15 wafers. A lower percentage of bubbling creates improved visual appearance and thus is preferred. Table 5 shows that the addition of pigment improves appearance by reducing bubbling.

### EXAMPLES 13 and 14

Examples 13 and 14 (Inventive) relate to adding pigment 200591 and pigment B214 to the composition of Example 1.

TABLE 6
Example 1 (Comparative) and Examples 13-14 (Inventive): Properties
of Aluminum Pastes after Addition of Inorganic Pigment.

| | Voc | Bowing | Yellow | Bubble |
|---|---|---|---|---|
| | (V) | (mm) | Index | (area %) |
| | [+/−0.0015 V] | [+/−0.10 mm] | [+/−0.1] | [+/−5%] |
| Ex. 1 | 0.6056 | 1.51 | 11.4 | 23 |
| (Compar- | | | | |
| ative): | | | | |
| LSF437W1 | | | | |
| Ex. 13 | 0.6037 | 1.30 | 7.1 | 38 |
| LSF437W1 + | | | | |
| 1.2% 30C591 | | | | |
| Ex. 14 | 0.6042 | 1.39 | 7.1 | 3.3 |
| LSF437W1 + | | | | |
| 1.2% B214 | | | | |

Table 6 shows further examples of the effect on various properties after adding inorganic pigment to Al pastes. It is understood that any amount from 0.01-5% inorganic pigment could be used, possibly even higher (up to 10%) in some cases depending on the individual inorganic pigment that is utilized. Table 6 shows electrical performance, bowing, color and appearance (bubble %) of these color-adjusted pastes, the methods of which are described in Tables 1-5. All test results are relative and depend on the wafer type used and the firing temperature fit for firing that type of wafer.

### Test Method for Assessing Performance of Examples 1 and 13-14 Pastes in Table 6:

Six-inch multi-crystalline Si wafers obtained from Zhejiang Soco Technology Co. Ltd of China were used. Al paste (1.35 g) was screen-printed on backside of Si wafers and dried using BTU International PVD-600 drying furnace with the following settings: speed=90 ipm; 310° C. (Zone 1); 290° C. (Zone 2); and 285° C. (Zone 3). The screen used for printing was 325 mesh, 23 micron wire diameter, and 10 micron emulsion, 45 degree bias. The squeegee used was 65-75 shore in hardness.

Ag paste was screen-printed on the front surface of the wafers, and dried in the drying furnace with the following settings: belt speed=165 ipm; 340° C. (Zone 1); 370° C. (Zone 2); and 370° C. (Zone 3). The screen used for printing is 325 mesh, 23 micron wire diameter, and 16 micron emulsion, 22.5 degree bias. The squeegee used is 65-75 shore in hardness. The wafers are fired using BTU International PVD-600 firing furnace with the following settings: belt speed=85 ipm; 700° C. (Zone 1); 640° C. (Zone 2); 640° C. (Zone 3); and 1000° C. (Zone 4).

The test methods for obtaining the results in Table 6 are the same as described in Tables 1-5. Table 6 shows that Voc is minimally affected by the addition of organic pigment, while bowing and yellowing are greatly improved. In the case of bubbling, Inventive Example 14 performed better than Inventive Example 13, pointing to B214 as a preferred inorganic pigment for the present invention. Example 13 was actually worse than Comparative Example 1 for bubbling, but showed improvement in other properties (bowing, yellowing).

### EXAMPLES 15 and 17

Example 15 (comparative) is commercially available Al paste Suntronic Cellmet LSF437W1 (Sun Chemical). Example 16 (inventive) is LSF437W1 with 1 wt % Elvacite 4021 acrylic resin added to the standard organic medium.

The aluminum paste is printed on the rear of an unmetallized silicon solar cell. The coverage is 5.6 mg/cm². The wafer is then dried in a standard IR belt furnace, and the front side is printed with a conventional silver paste. The wafer is then fired in a belt furnace at a temperature and speed which maximizes the efficiency of the cell. For the silver paste used, there was a spike firing at high speed (180-220 inches/min) and high temperature (750-850° C.). The efficiency of the solar cells was measured using a Solar Simulator/I-V tester from PV Measurements Inc. The illumination of the lamp was calibrated using a sealed calibration cell, and the measured characteristics were adjusted to standard AM1.5G illumination conditions (1000 mW/cm²). During testing, the cells were positioned on a vacuum chuck located under the lamp and the chuck temperature was maintained at 24° C.+/−1 using a chiller. Both dark and light I-V curves were collected by sweeping voltage between −0.2V and +1.2V and measuring current. Standard solar cell electrical parameters were collected from the instrument including Cell Efficiency (%), Series resistance (Rseries), Shunt Resistance (Rshunt) and Open Circuit Voltage (Voc). Bowing is tested by a Keyence laser displacement sensor 30 minutes after the firing. The sensor measured the deviation of the height of the wafer from completely flat in the center of the wafer. Cosmetic defects were evaluated visually, where the approximate percentage of the back side which has various bubbling or marbling is noted. Sheet resistance was measured by a calibrated Jandel 4-point probe with an excitation current of 99 mA. Yellowness was measured by an X-Rite Spectro-Eye spectro-densitometer and characterized by yellowness index following ASTM Standard E313.

TABLE 7
Example 15 (Comparative) and Example 16 (Inventive): Properties
of Aluminum Pastes after Addition of Acrylic Resin.

| | | Bowing | Bubbling | Voc | Rsheet |
|---|---|---|---|---|---|
| Example | Description | (mm) | (%) | (mV) | mOhm/sq |
| 15 | Cellmet 437W1 | 1.80 | 50% | 620 | 9.6 |
| (compar- | | | | | |
| ative) | | | | | |
| 16 | Ex. 1A + 1 wt % | 1.53 | 0% | 620 | 8.3 |
| (inventive) | Elvacite 4021 | | | | |

Table 7 shows the data taken from an aggregate of 10 samples. We see that the Inventive Example 16 containing acrylic resin in the organic medium has lower bowing, decreased bubbling, and decreased sheet resistance with equal Voc vs. Comparative Example 15.

### EXAMPLES 17 and 18

Example 17 (comparative) is commercially available Al paste Suntronic Cellmet LSF437W1 (Sun Chemical). Example 18 (inventive) is LSF437W1 with 2 wt % IsoCarb161 wt % branched fatty acid added to the standard organic medium.

The aluminum paste is printed on the rear of an unmetallized silicon solar cell. The coverage is 5.6 mg/cm2. The wafer is then dried in a standard IR belt furnace, and the front side is printed with a conventional silver paste. The wafer is then fired in a belt furnace at a temperature and speed which maximizes the efficiency of the cell. For the silver paste used, there was a spike firing at high speed (180-220 inches/min) and high temperature (750-850° C.). The efficiency of the solar cells were measured using a Solar Simulator/I-V tester from PV Measurements Inc. The illumination of the lamp was calibrated using a sealed calibration cell, and the measured characteristics were adjusted to standard AM1.5G illumination conditions (1000 mW/cm2). During testing, the cells were positioned on a vacuum chuck located under the lamp and the chuck temperature was maintained at 24° C.+/−1 using a chiller. Both dark and light I-V curves were collected by sweeping voltage between −0.2V and +1.2V and measuring current. Standard solar cell electrical parameters were collected from the instrument including Cell Efficiency (%), Series resistance (Rseries), Shunt Resistance (Rshunt) and Open Circuit Voltage (Voc). Bowing is tested by a Keyence laser displacement sensor 30 minutes after the firing. The sensor measured the deviation of the height of the wafer from completely flat in the center of the wafer. Cosmetic defects were evaluated visually, where the approximate percentage of the back side which has various bubbling or marbling is noted. Sheet resistance was measured by a calibrated Jandel 4-point probe with an excitation current of 99 mA. Yellowness was measured by an X-Rite Spectro-Eye spectro-densitometer and characterized by yellowness index following ASTM std E313.

TABLE 8
Example 17 (Comparative) and Example 18 (Inventive): Properties
of Aluminum Pastes after Addition of Branched Fatty Acid.

| | | Efficiency | Voc | Bub- | Mar- |
|---|---|---|---|---|---|
| Example | Description | (%) | (mV) | bling | bling |
| 17 | Cellmet 437W1 | 17.3% | 621.5 | 50-100% | 50-55% |
| (compar- | | | | | |
| ative) | | | | | |
| 18 | Ex. 2A + 2 wt % | 17.4% | 622 | 0-5% | 0-25% |
| (inventive) | IsoCarb16 | | | | |

Table 8 (average of 15 samples) shows the result of an experiment where branched fatty acid was added to the standard organic material. We see increases in the efficiency and the Voc of Inventive Example 18 when compared to the Comparative Example 17 over a large data set. Significant decreases in bubbling and marbling are observed at the standard firing temperature, which is indicative of an increase in the firing window.

### EXAMPLES 19 and 20

Example 19 (comparative) is commercially available Al paste Suntronic Cellmet LSF437W1 (Sun Chemical). Example 20 (inventive) is LSF437W1 with 1 wt % Isofol 18T fatty alcohol added to the standard organic medium.

The aluminum paste is printed on the rear of an unmetallized silicon solar cell. The coverage is 5.6 mg/cm2. The wafer is then dried in a standard IR belt furnace, and the front side is printed with a conventional silver paste. The wafer is then fired in a belt furnace at a temperature and speed which maximizes the efficiency of the cell. For the silver paste used, there was a spike firing at high speed (180-220 inches/min) and high temperature (750-850° C.). The efficiency of the solar cells were measured using a Solar Simulator/I-V tester from PV Measurements Inc. The illumination of the lamp was calibrated using a sealed calibration cell, and the measured characteristics were adjusted to standard AM1.5G illumination conditions (1000 mW/cm2). During testing, the cells were positioned on a vacuum chuck located under the lamp and the chuck temperature was maintained at 24° C.+/−1 using a chiller. Both dark and light I-V curves were collected by sweeping voltage between −0.2V and +1.2V and measuring current. Standard solar cell electrical parameters were collected from the instrument including Cell Efficiency (%), Series resistance (Rseries), Shunt Resistance (Rshunt) and Open Circuit Voltage (Voc). Bowing is tested by a Keyence laser displacement sensor 30 minutes after the firing. The sensor measured the deviation of the height of the wafer from completely flat in the center of the wafer. Cosmetic defects were evaluated visually, where the approximate percentage of the back side which has various bubbling or marbling is noted. Sheet resistance was measured by a calibrated Jandel 4-point probe with an excitation current of 99 mA. Yellowness was measured by an X-Rite Spectro-Eye spectro-densitometer and characterized by yellowness index following ASTM Standard E313.

TABLE 9
Example 19 (Comparative) and Example 20 (Inventive): Properties
of Aluminum Pastes after Addition of Fatty Alcohol.

| | | Bowing | Efficiency | Voc | | |
|---|---|---|---|---|---|---|
| Example | Description | (mm) | (%) | (mV) | Bubbling | Yellowness |
| 19 (comparative) | Cellmet 437W1 | 1.79 | 17.1 | 615 | 50% | 12.25% |
| 20 (inventive) | Ex. 3A + 1 wt % | 1.59 | 17.1 | 615 | 0% | 10.44% |
| | Isofol 18T | | | | | |

Table 9 (average of 10 measurements) shows the effect of the addition of fatty alcohol to the standard organic package. We see reductions in bowing, bubbling and yellowness for Inventive Example 20 paste when compared to Comparative Example 19. Efficiency and Voc are unchanged for the two samples, thus realizing improvements in the bubbling, bowing and yellowness without a loss in performance.

All references cited herein are herein incorporated by reference in their entirety for all purposes.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the invention.

We claim:

1. An aluminum paste for silicon solar cells comprising:
(a) an aluminum powder;
(b) a glass frit;
(c) an organic resin;
(d) a solvent; and
(e) an organic or inorganic pigment,
wherein, said aluminum paste is suited for use in the manufacture of silicon solar cells.

2. The paste of claim 1, in which the pigment is inorganic.

3. The paste of claim 2, comprising about 0.3-2.0% inorganic pigment.

4. The paste of claim 1, further comprising one or more from the group consisting of: dispersant(s), metal oxide(s), metal organic additive(s), adhesion promoting agent(s) and thixotropic agent(s).

5. The paste of claim 1 comprising:
(a) 0.1-5% inorganic pigment(s)
(b) 0.5-10% glass frit(s);
(c) 0.2-1.0% dispersant(s);
(d) 50-85% Al powder(s);
(e) 0.1-2.0% metal organics additive(s);
(f) 0-5% metal oxide(s);
(g) 0.2-10% resin(s);
(h) 5-20% solvent(s);
(i) 0-2% thixotropic agent(s); and
(j) 0-0.7% adhesion-promoting agent(s)

6. The paste of claim 4 in which the metal organic additive is a tri-methyl borate.

7. The paste of claim 4 in which the dispersant is a fatty acid.

8. The paste of claim 1, in which the glass frit is selected from the group consisting of B₂O₃, Bi₂O₃, ZnO, SiO₂, Al₂O₃, BaO and combinations thereof.

9. The paste of claim 1 with the Al powder(s) having a particle size in the range of about 1-7 um.

10. The paste of claim 4 in which the metal organics additive(s) is liquid.

11. The paste of claim 4 in which the metal organics additive(s) is selected from the group consisting of organics of Boron, Zinc, Vanadium, Barium, Strontium, and/or Aluminum, and combinations thereof.

12. The paste of claim 1, wherein the pigment comprises cobalt aluminate CoO.Al₂O₃

13. The paste of claim 1, wherein the pigment is selected from the group consisting of Shepherd Blue 214 and 30C591, and combinations thereof.

14. A process for making a crystalline silicon solar cell, comprising mixing the composition of claim 1.

15. A c-Si solar cell comprising the composition of any claim 1.

16. An aluminum paste for the manufacture of solar cells comprising:
(a) an aluminum powder;
(b) a glass frit; and
(c) an organic medium comprising one or more compounds selected from the group consisting of: a straight or branched chain fatty alcohol, straight or branched chain branched fatty acid, and an acrylic resin.

17. The paste of claim 16, wherein the organic medium comprises an acrylic resin.

18. The paste of claim 17, wherein the acrylic resin has a molecular weight between about 20,000 and 200,000.

19. The paste of claim 16, wherein the organic medium comprises a straight or branched chain fatty alcohol.

20. The paste of claim 16, wherein the organic medium comprises a straight or branched chain fatty acid.

21. A process for making a crystalline silicon solar cell, comprising mixing the composition of claim 16.

22. A c-Si solar cell comprising the paste of claim 16.

23. The paste of claim 16 further comprising an organic or inorganic pigment.
